(19) United States
(12) Patent Application Publication
(10) Pub. No.: US 2026/0052780 A1
(43) Pub. Date: Feb. 19, 2026

(54) ELECTROSTATIC DISCHARGE PROTECTION STRUCTURE AND CIRCUIT

(71) Applicant: Vanguard International Semiconductor Corporation, Hsinchu (TW)

(72) Inventors: Ting-Yu CHANG, Zhubei City (TW); Yeh-Ning JOU, Hsinchu City (TW); Chieh-Yao CHUANG, Kaohsiung City (TW); Chih-Hsuan LIN, Hsinchu City (TW); Hsien-Feng LIAO, Taichung City (TW)

(73) Assignee: Vanguard International Semiconductor Corporation, Hsinchu (TW)

(21) Appl. No.: 18/808,562

(22) Filed: Aug. 19, 2024

(51) Int. Cl. H01L 27/02; H01L 27/06

(52) U.S. Cl. CPC H10D 89/811; H10D 84/401

(57) ABSTRACT

An electrostatic discharge protection structure is provided. A deep-well region is disposed in a substrate. First to third wells are disposed on the deep-well region. First to third doped regions are disposed in the first well. A gate structure is disposed on the substrate and between the first and second doped regions. A fourth doped region is disposed in the second well region. A fifth doped region and a sixth doped region are disposed in the third well. An interconnection structure is electrically connected to the gate structure, and the second, third, and fourth doped regions. Each of the substrate, the first and third well regions, and the third and sixth doped regions has a first conductivity type. Each of the deep-well region, the second well region, and the first, second, fourth and fifth doped regions has a second conductivity type.

### BACKGROUND OF THE INVENTION

### Field of the Invention

The present invention relates to an electrostatic discharge (ESD) protection structure, and, in particular, to an ESD protection structure that reduces negative current.

### Description of the Related Art

As the semiconductor manufacturing process develops, electrostatic discharge (ESD) protection has become one of the most critical reliability issues for integrated circuits (IC). In particular, as semiconductor manufacturing advances into the deep sub-micron stage, scaled-down devices and thinner gate oxides are more vulnerable to ESD stress.

Generally, the input-output pads on IC chips must at least sustain 2 KVolt ESD stress of high Human Body Mode (HBM) or 200V of Machine Mode (MM). Thus, the input-output pads on IC chips usually include ESD protection devices or circuits protecting the core circuit from ESD damage.

### BRIEF SUMMARY OF THE INVENTION

In accordance with an embodiment of the disclosure, an electrostatic discharge (ESD) protection structure comprises a substrate, a deep-well region, a first well region, a second well region, a third well region, a first doped region, a second doped region, a third doped region, a fourth doped region, a fifth doped region, a sixth doped region, a gate structure, and an interconnection structure. The substrate comprises a first conductivity type. The deep-well region is disposed in the substrate and comprises a second conductivity type. The first well region is disposed on the deep-well region and comprises the first conductivity type. The second well region is disposed on the deep-well region and comprises the second conductivity type, The third well region is disposed on the deep-well region and comprises the first conductivity type. The first doped region is disposed in the first well region and comprises the second conductivity type. The second doped region is disposed in the first well region and comprises the second conductivity type. The third doped region is disposed in the first well region and comprises the first conductivity type. The gate structure is disposed on the substrate and between the first doped region and the second doped region. The fourth doped region is disposed in the second well region and comprises the second conductivity type. The fifth doped region is disposed in the third well region and comprises the second conductivity type. The sixth doped region is disposed in the third well region and comprises the first conductivity type. The interconnection structure is electrically connected to the gate structure, the second doped region, the third doped region, and the fourth doped region. The first doped region, the second doped region, the third doped region, and the gate structure constitute a metal oxide semiconductor field effect transistor (MOSFET). The fourth doped region, the fifth doped region, and the sixth doped region constitute a bipolar junction transistor (BJT).

In accordance with another embodiment of the disclosure, an ESD protection circuit for protecting a core circuit, comprises a substrate, an N-type MOSFET and a BJT. The N-type MOSFET is formed on the substrate and comprises a drain which is coupled to a first input-output pad;. The BJT is formed on the substrate. The collector of the BJT is coupled to the gate, the source and the bulk of the N-type MOSFET. The emitter and the base of the BJT are coupled to a second input-output pad. The core circuit is coupled between the first input-output pad and the second input-output pad.

### BRIEF DESCRIPTION OF THE DRAWINGS

The present invention can be more fully understood by reading the subsequent detailed description and examples with references made to the accompanying drawings, wherein:

FIG. 1 is a schematic diagram of an exemplary embodiment of an electrostatic discharge (ESD) protection structure according to various aspects of the present disclosure.

FIG. 2A is a top-view schematic diagram of an exemplary embodiment of the ESD protection structure according to various aspects of the present disclosure.

FIG. 2B is a top-view schematic diagram of another exemplary embodiment of the ESD protection structure according to various aspects of the present disclosure.

FIG. 2C is a top-view schematic diagram of another exemplary embodiment of the ESD protection structure according to various aspects of the present disclosure.

FIG. 3 is a schematic diagram of an exemplary embodiment of an operation circuit according to various aspects of the present disclosure.

### DETAILED DESCRIPTION OF THE INVENTION

The present invention will be described with respect to particular embodiments and with reference to certain drawings, but the invention is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the invention.

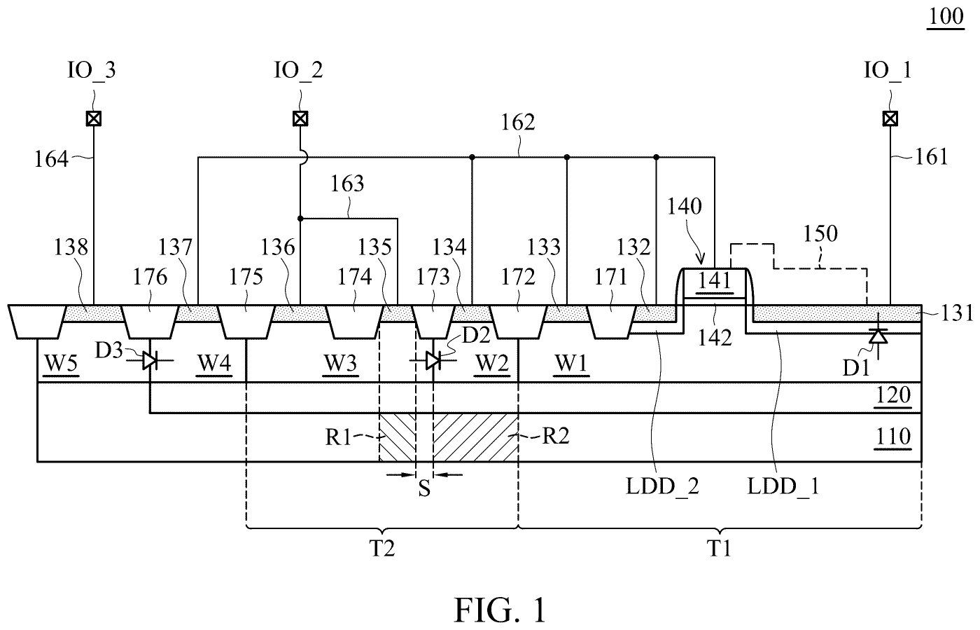

FIG. 1 is a schematic diagram of an exemplary embodiment of an electrostatic discharge (ESD) protection structure according to various aspects of the present disclosure. The ESD protection structure 100 comprises a substrate 110, a deep-well region 120, well regions W1˜W3, doped regions 131˜136, and a gate structure 140. The substrate 110 comprises a first conductivity type. The deep-well region 120 is disposed in the substrate 110 and comprises a second conductivity type. The second conductivity type is different from the first conductivity type. In one embodiment, the first conductivity type is a P-type, and the second conductivity type is an N-type. In another embodiment, the first conductivity type is an N-type, and the second conductivity type is a P-type.

The well region W1 is disposed on the deep-well region 120 and comprises the first conductivity type. In one embodiment, the impurity concentration of the well region W1 is higher than the impurity concentration of the 110. The well region W2 is disposed on the deep-well region 120 and disposed between the well regions W1 and W3. In this embodiment, the well region W2 comprises the second conductivity type. The impurity concentration of the well region W2 is higher than the impurity concentration of the deep-well region 120. The well region W3 is disposed on the deep-well region 120 and comprises the first conductivity type. In one embodiment, the impurity concentration of the well region W3 is similar to the impurity concentration of the well region W1.

The doped regions 131 and 132 are disposed in the well region W1 and comprise the second conductivity type. In this embodiment, the impurity concentration of the doped region 131 is similar to the impurity concentration of the doped region 132 and higher than the impurity concentration of the well region W2. The doped region 133 is disposed in the well region W1 and comprises the first conductivity type. In one embodiment, the impurity concentration of the doped region 133 is higher than the impurity concentration of the well region W1.

The gate structure 140 is disposed on the substrate 110 and disposed between the doped regions 131 and 132. In this embodiment, the gate structure 140 comprises a gate electrode layer 141 and a gate dielectric layer 142. The gate dielectric layer 142 is formed on a portion of the surface of the substrate 110. The gate electrode layer 141 is disposed on the gate dielectric layer 142. In other embodiments, the ESD protection structure 100 further comprises a resistive protective oxide (RPO) layer 150. The RPO layer 150 covers a portion of the top-surface of the gate structure 140 and a portion of the top-surface of the doped region 131.

In some embodiments, the ESD protection structure 100 further comprises lightly doped drain (LDD) regions LDD_1 and LDD_2. Each of the LDD regions LDD_1 and LDD_2 is disposed in the well region W1 and comprises the second conductivity type. The LDD region LDD_1 surrounds the doped region 131. The LDD region LDD_2 surrounds the doped region 132. In one embodiment, the impurity concentration of the LDD region LDD_1 is similar to the impurity concentration of the LDD region LDD_2. In this case, the impurity concentration of the LDD region LDD_1 is lower than the impurity concentration of the doped region 131, and the impurity concentration of the LDD region LDD_2 is lower than the impurity concentration of the doped region 132.

In one embodiment, the doped regions 131˜133 and the gate structure 140 constitute a metal oxide semiconductor field effect transistor (MOSFET) T1. The doped region 131 serves as the drain of the MOSFET T1. The doped region 132 serves as the source of the MOSFET T1. The doped region 133 serves as the bulk of the MOSFET T1. The gate structure 140 serves as the gate of the MOSFET t1.

The type of MOSFET T1 is not limited in the present disclosure. In one embodiment, when the first conductivity type is a P-type and the second conductivity type is an N-type, the MOSFET T1 is an N-type MOSFET. In another embodiment, when the first conductivity type is an N-type and the second conductivity type is a P-type, the MOSFET T1 is a P-type MOSFET.

The doped region 134 is disposed in the well region W2 and comprises the second conductivity type. In this embodiment, the impurity concentration of the doped region 134 is similar to the impurity concentration of the doped region 132 and higher than the impurity concentration of the well region W2. The doped region 135 is disposed in the well region W3 and comprises the second conductivity type. In this embodiment, the impurity concentration of the doped region 135 is similar to the impurity concentration of the doped region 134. The doped region 136 is disposed in the well region W3 and comprises the first conductivity type. In this embodiment, the impurity concentration of the doped region 136 is similar to the impurity concentration of the doped region 133 and higher than the impurity concentration of the well region W3.

In one embodiment, the doped regions 134˜136 constitute a bipolar junction transistor (BJT) T2. The doped region 134 may serve as the collector of the BJT T2. The doped region 135 may serve as the emitter of the BJT T2. The doped region 136 may serve as the base of the BJT T2. In some embodiments, when the first conductivity type is a P-type and the second conductivity type is an N-type, the BJT T2 is an NPN-type BJT.

In some embodiments, the ESD protection structure 100 further comprises interconnection structures 161˜164. The interconnection structure 161 is electrically connected to the doped region 131 and an input-output pad IO_1. The interconnection structure 162 is electrically connected to the gate structure 140, and the doped regions 132˜134. In this embodiment, the interconnection structure 162 does not be coupled to any input-output pad. Therefore, the gate structure 140 and the doped regions 132˜134 are electrically floating. The interconnection structure 163 is electrically connected to the doped regions 135 and 136, and an input-output pad IO_2. In one embodiment, the input-output pad IO_1 receives a first operation voltage, and the input-output pad IO_2 receives a second operation voltage. In this case, the first operation voltage is higher than the second operation voltage. In some embodiments, the second operation voltage is a ground voltage.

In other embodiments, the ESD protection structure 100 further comprises well regions W4 and W5, and the doped regions 137 and 138. The well region W4 is disposed on the deep-well region 120 and comprises the second conductivity type. The doped region 137 is disposed in the well region W4 and comprises the second conductivity type. In one embodiment, the impurity concentration of the doped region 137 is higher than the impurity concentration of the well region W4 and similar to the impurity concentration of the doped region 131. The impurity concentration of the well region W4 is similar to the impurity concentration of the well region W2. In some embodiments, the doped region 137 is electrically connected to the interconnection structure 162.

The well region W5 is disposed in the substrate 110 and comprises the first conductivity type. In one embodiment, the impurity concentration of the well region W5 is similar to the impurity concentration of the well region W3. The doped region 138 is disposed in the well region W5 and comprises the first conductivity type. In one embodiment, the impurity concentration of the doped region 138 is higher than the impurity concentration of the well region W5 and similar to the impurity concentration of the doped region 136.

In some embodiments, the ESD protection structure 100 further comprises an interconnection structure 164. The interconnection structure 164 is electrically connected to the doped region 138 and the input-output pad IO_3. In this case, the input-output pad IO_3 receives a third operation voltage. The third operation voltage may be equal to or less than the second operation voltage. In one embodiment, the third operation voltage is a ground voltage.

In other embodiments, the ESD protection structure 100 further comprises isolation structures 171˜176. The isolation structure 171 is disposed in the well region W1 and is spaced apart the doped region 132 from the doped region 133. The isolation structure 172 covers a portion of the well region W1 and a portion of the well region W2. The isolation structure 172 is spaced apart the doped region 133 from the doped region 134. The isolation structure 173 covers a portion of the well region W2 and a portion of the well region W3. The isolation structure 173 is spaced apart the doped region 134 from the doped region 135. The isolation structure 174 is disposed in the well region W3 and spaced the doped region 135 from the doped region 136. The isolation structure 175 coverts a portion of the well region W3 and a portion of the well region W4. The isolation structure 175 is spaced apart the doped region 136 from the doped region 137. The isolation structure 176 covers a portion of the well region W4 and a portion of the well region W5. The isolation structure 176 is spaced apart the doped region 137 from the doped region 138. In one embodiment, the isolation structures 171˜176 are field oxide layers, but the disclosure is not limited thereto. In other embodiments, the isolation structures 171˜176 may be other isolation structures, such as shallow trench isolation (STI) structures.

In this embodiment, there is a distance S between a projection area R1 of the doped region 135 on the substrate 110 and a projection area R2 of the well region W2 on the substrate 110. The distance S is related to the breakdown voltage of the ESD protection structure 100. For example, when the distance S decreases, the breakdown voltage of the ESD protection structure 100 also decreases. In another embodiment, the distance S is related to the effectiveness of the Human Body Model (HBM) and the Machine Model (MM) of the ESD protection structure 100. When the distance S decreases, the effectiveness of HBM and MM of the ESD protection structure 100 are enhanced. In one embodiment, the distance S is larger than 0.7 micrometer (μm). In another embodiment, the distance S is higher than or equal to 1 μm.

In this embodiment, the PN junction between the well region W1 and the doped region 131 is equivalent to a diode D1, the PN junction between the well regions W2 and W3 is equivalent to a diode D2, and the PN junction between the well regions W5 and W4 is equivalent to a diode D3. When a first ESD voltage is applied on the input-output pad IO_1 and the input-output pads IO_2 and IO_3 receive a ground voltage, a first ESD current enters the doped region 131 from the input-output pad IO_1. Therefore, a reverse voltage is applied to the diode D1 so that the diode D1 is reversely turned on. At this time, the voltage of the well region W1 increased so that the MOSFET T1 is turned on. A first ESD current flows from the doped region 131, the well region W1, the doped region 132, the interconnection structure 162, and the doped region 134 to the well region W2. When the diode D2 is reversely turned on, the voltage of the well region W3 increased so that the BJT T2 is turned on. Therefore, the first ESD current flows from the well region W2 and the doped region 135 to the input-output pad IO_2 releasing ESD stress. In this embodiment, the doped region 131, the well region W1, the doped region 132, the interconnection structure 162, the doped region 134, the well region W2, the well region W3, and the doped region 135 constitute a discharge path (or referred to as a first charge path). In this case, the first ESD voltage is higher than the ground voltage.

When a second ESD voltage is applied on the input-output pad IO_1 and each of the input-output pads IO_2 and IO_3 receives a ground voltage, a second ESD current may be released to the input-output pad IO_2 through the diodes D1 and D2 or released to the input-output pad IO_3 through the diodes D1 and D3. In this case, the second ESD voltage is less than the ground voltage.

For example, when a second ESD voltage is applied on the input-output pad IO_1 and each of the input-output pads IO_2 and IO_3 receives a ground voltage, a second ESD current enters the doped region 131 from the input-output pad IO_1. Therefore, the diode D1 is forwardly turned on. The second ESD current passes through the well region W1, the doped region 133, the interconnection structure 162, and the doped region 134 to the well region W2. Since the diode D2 is forwardly turned on, the second ESD current enters the well region W3 and passes through the doped region 131 to the input-output pad IO_2. In this case, the doped region 131, the well region W1, the doped region 133, the interconnection structure 162, the doped region 134, the well region W2, the well region W3, and the doped region 136 constitute a discharge path (referred to as a second discharge path).

In another embodiment, the second ESD current may enter the doped region 137 and the well region W4 via the interconnection structure 162. At this time, since the diode D3 is forwardly turned on, the second ESD current enters the well region W and passes through the doped region 138 to the input-output pad IO_3. In this case, the doped region 131, the well region W1, the doped region 133, the interconnection structure 162, the doped region 137, the well region W4, the well region W5, and the doped region 138 constitute another discharge path (or referred to as a third discharge path).

Since the ESD protection structure 100 comprises the MOSFET T1 and the BJT t2, the leakage current of the ESD protection structure 100 can be reduced in a normal mode (no ESD event). Additionally, even if the input-output pad IO_1 receives a negative voltage, or the ESD protection structure 100 is in a high temperature environment, the leakage current of the ESD protection structure 100 can be reduced because the MOSFET T1 and the BJT T2 are integrated together.

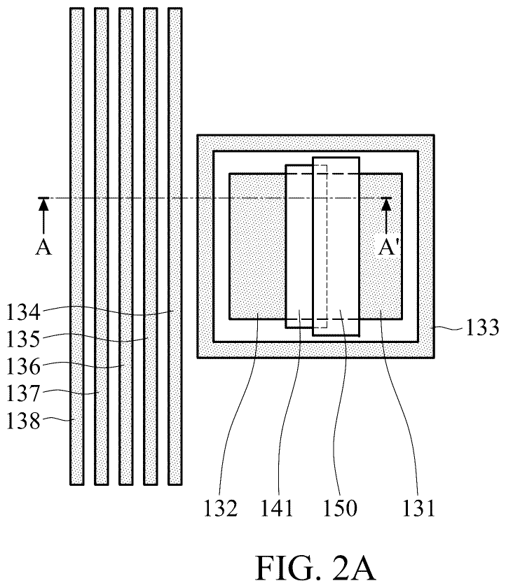

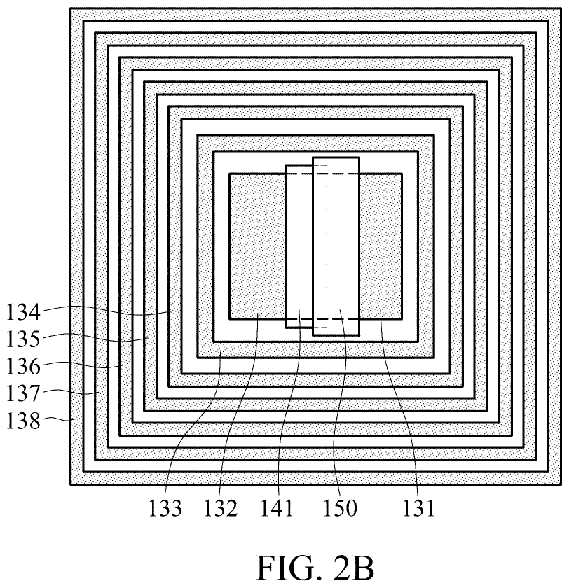

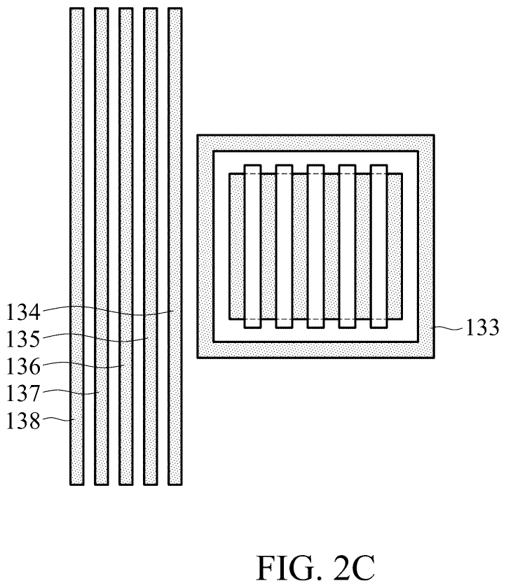

FIG. 2A is a top-view schematic diagram of an exemplary embodiment of the ESD protection structure according to various aspects of the present disclosure. In this embodiment, FIG. 1 illustrates a cross-sectional view of the structure shown in FIG. 2A, wherein the cross-sectional view is obtained from the plane containing A-A′ in FIG. 2A. As shown in FIG. 2A, the doped region 133 takes the form of a ring surrounding the doped region 131, the doped region 132, the gate electrode layer 141, and the RPO layer 150. Each of the doped regions 134˜138 has a strip shape and is located on the left periphery of the doped region 133.

FIG. 2B is a top-view schematic diagram of another exemplary embodiment of the ESD protection structure according to various aspects of the present disclosure. In this embodiment, each of the doped regions 134˜138 has a ring shape surrounding the MOSFET T1. As shown in FIG. 2B, the doped region 134 surrounds the doped region 133. The doped region 135 surrounds the doped region 134. The doped region 136 surrounds the doped region 135. The doped region 137 surrounds the doped region 136. The doped region 138 surrounds the doped region 137.

FIG. 2C is a top-view schematic diagram of another exemplary embodiment of the ESD protection structure according to various aspects of the present disclosure. FIG. 2C is similar to FIG. 2A except that the doped region 133 shown in FIG. 2A surrounds a single MOSFET (e.g., T1) and the doped region 133 shown in FIG. 2C surrounds various MOSFETs. In one embodiment, the MOSFETs surrounded by the doped region 133 shown in FIG. 2C are connected to each other in parallel. In other embodiments, the MOSFETs shown in FIG. 2C may be applied to FIG. 2B. In other words, the doped region 133 shown in FIG. 2C may be surrounded by the doped regions 134˜138.

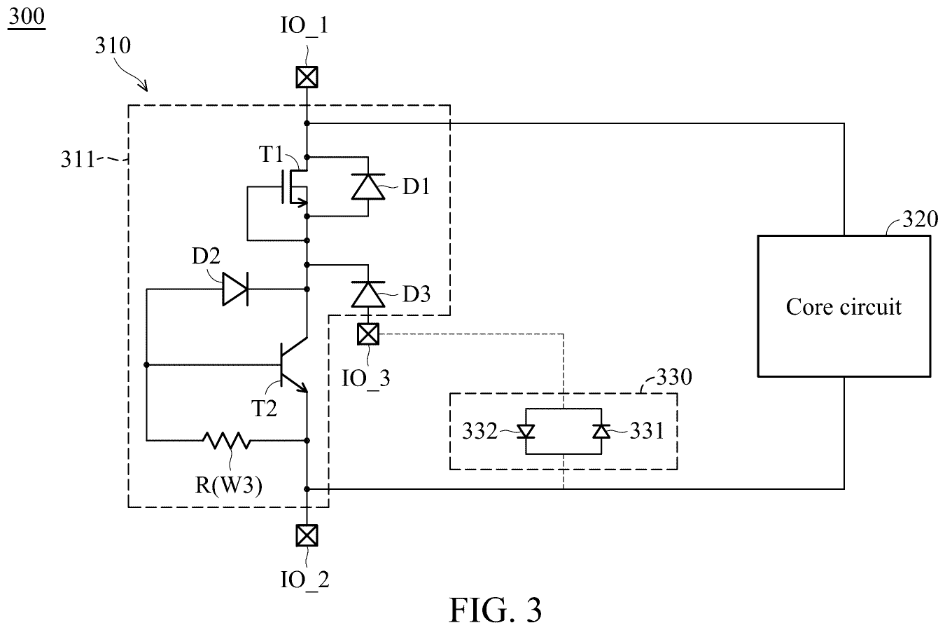

FIG. 3 is a schematic diagram of an exemplary embodiment of an operation circuit according to various aspects of the present disclosure. The operation circuit 300 comprises an ESD protection circuit 310 and a core circuit 320. The ESD protection circuit 310 is connected to the core circuit 320 in parallel between the input-output pads IO_1 and IO_2. The ESD protection circuit 310 protects the core circuit 320 to prevents the ESD current from the input-output pad IO_1 or IO_2 from entering the core circuit 320. In this embodiment, the ESD protection circuit 310 is an equivalent circuit of the ESD protection structure 100 in FIG. 1.

The ESD protection circuit 310 comprises a substrate 311, a MOSFET T1, and a BJT T2. The MOSFET T1 and the BJT T2 are formed on the substrate 311. In this embodiment, the input-output pad IO_3 serves as an electrical contact of the substrate 311.

The drain of the MOSFET T1 is coupled to the input-output pad IO_1. In this embodiment, the MOSFET T1 is an N-type MOSFET. The collector of the BJT T2 is coupled to the gate, the source, and the bulk of the MOSFET T1. In one embodiment, the gate, the source and the bulk of the MOSFET T1 are directly connected to the collector of the BJT T2. In some embodiments, the gate, the source and the bulk of the MOSFET T1 are electrically floating. In other words, the voltage level of each of the gate, the source and the bulk of the MOSFET T1 is a floating level. Additionally, the emitter and the base of the BJT T2 are coupled to the input-output pad IO_2. In this embodiment, the BJT T2 is an NPN-type BJT.

In one embodiment, the collector of the BJT T2 is disposed in an N-type well region, such as the well region W2 of FIG. 1. In this case, there is a distance between a protection area of the N-type well region on the substrate 311 and the emitter (e.g., the doped region 135 of FIG. 1) of the BJT T2 on the substrate 311. The distance may be within 0.7 μm˜1 μm. In another embodiment, the distance is larger than or equal to 1 μm. Additionally, the resistor R shown in FIG. 3 represents the equivalent resistance of the well region W3 of FIG. 1.

When the input-output pad IO_1 receives a first ESD voltage and the input-output pad IO_2 receives a ground voltage, a first ESD current passes through the diode D1 between the drain and the bulk of the MOSFET T1. Therefore, the MOSFET T1 is turned on. At this time, the first ESD current passes through the diode D2 between the collector and the base of the BJT T2. Therefore, the BJT T2 is turned on and the first ESD current enters the input-output pad IO_2 from the input-output pad IO_1. In this embodiment, the first ESD voltage is higher than the ground voltage.

When the input-output pad IO_1 receives a second ESD voltage and each of the input-output pads IO_2 and IO_3 receives a ground voltage, a second ESD current passes through a string of diodes. In one embodiment, the string of diodes comprises the diode D1 between the drain and the bulk of the MOSFET T1 and the diode D2 between the collector and the base of the BJT T2. In another embodiment, the string of diodes comprises the diode D1 between the drain and the bulk of the MOSFET T1 and the diode D3 between the collector of the BJT T2 and the substrate 311. In some embodiments, the second ESD voltage is lower than the ground voltage.

In other embodiments, the input-output pad IO_3 is directly connected to the input-output pad IO_2. In another embodiment, the operation circuit 300 further comprises a processing circuit 330. The processing circuit 330 is coupled between the input-output pads IO_2 and IO_3 to prevent the voltages of the input-output pads IO_2 and IO_3 from interfering with each other. In one embodiment, the processing circuit 330 comprises diodes 331 and 332. The cathode of the diode 331 is coupled to the input-output pad IO_3. The anode of the diode 331 is coupled to the input-output pad io_2. The cathode of the diode 332 is coupled to the input-output pad IO_2. The anode of the diode 332 is coupled to the input-output pad IO_3. In another embodiment, the processing circuit 330 comprises at least one resistor. In this case, the resistor is coupled between the input-output pads IO_2 and IO_3.

It will be understood that when an element or layer is referred to as being “coupled to” another element or layer, it can be directly on, connected or coupled to the other element or layer or intervening elements or layers may be present. In contrast, when an element or layer is referred to as be “directly connected to” or “directly coupled to” another element or layer, there are no intervening elements or layers present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another. In the following claims, the terms “first,” “second,” etc. are used merely as labels, and are not intended to impose numerical requirements on their objects.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electrostatic discharge (ESD) protection structure, comprising:
a substrate comprising a first conductivity type;
a deep-well region disposed in the substrate and comprising a second conductivity type;
a first well region disposed on the deep-well region and comprising the first conductivity type;
a second well region disposed on the deep-well region and comprising the second conductivity type;
a third well region disposed on the deep-well region and comprising the first conductivity type;
a first doped region disposed in the first well region and comprising the second conductivity type;
a second doped region disposed in the first well region and comprising the second conductivity type;
a third doped region disposed in the first well region and comprising the first conductivity type;
a gate structure disposed on the substrate and disposed between the first doped region and the second doped region;
a fourth doped region disposed in the second well region and comprising the second conductivity type;
a fifth doped region disposed in the third well region and comprising the second conductivity type;
a sixth doped region disposed in the third well region and comprising the first conductivity type; and
a first interconnection structure electrically connected to the gate structure, the second doped region, the third doped region, and the fourth doped region,
wherein:
the first doped region, the second doped region, the third doped region, and the gate structure constitute a metal oxide semiconductor field effect transistor (MOSFET), and
the fourth doped region, the fifth doped region, and the sixth doped region constitute a bipolar junction transistor (BJT).

2. The ESD protection structure as claimed in claim 1, wherein there is a distance between a first projection area of the fifth doped region on the substrate and a second projection area of the second well region on the substrate.

3. The ESD protection structure as claimed in claim 2, wherein the distance is higher than 1 micrometer (μm).

4. The ESD protection structure as claimed in claim 1, further comprising:
a second interconnection structure electrically connected to the fifth doped region and the sixth doped region.

5. The ESD protection structure as claimed in claim 4, wherein:
the fourth doped region takes the form of a first ring surrounding the MOSFET,
the fifth doped region takes the form of a second ring surrounding the fourth doped region; and
the sixth doped region takes the form of a third ring surrounding the fifth doped region.

6. The ESD protection structure as claimed in claim 5, further comprising:
a fourth well region disposed on the deep-well region and comprising the second conductivity type;
a fifth well region disposed in the substrate and comprising the first conductivity type;
a seventh doped region disposed in the fourth well region and comprising the second conductivity type; and
an eighth doped region disposed in the fifth well region and comprising the first conductivity type,
wherein the first interconnection structure is electrically connected to the seventh doped region.

7. The ESD protection structure as claimed in claim 6, wherein:
the seventh doped region takes the form of a fourth ring surrounding the sixth doped region, and
the eighth doped region takes the form of a fifth ring surrounding the seventh doped region.

8. The ESD protection structure as claimed in claim 6, wherein:
the first doped region is coupled to a first input-output pad, and the eighth doped region is coupled to a second input-output pad,
in response to a first ESD voltage being applied on the first input-output pad and the second input-output pad and the second interconnection structure receiving a ground voltage, a first ESD current passes through the first input-output pad, the first doped region, a first discharge path, and finally to the second input-output pad,
in response to a second ESD voltage being applied on the first input-output pad and the second input-output pad and the second interconnection structure receiving the ground voltage, a second ESD current is released along a second discharge path to the second interconnection structure or along a third discharge path to the second input-output pad,
the first ESD voltage is higher than the ground voltage, and the second ESD voltage is lower than the ground voltage.

9. The ESD protection structure as claimed in claim 8, wherein the first doped region, the first well region, the second doped region, the first interconnection structure, the fourth doped region, the second well region, the third well region, and the fifth doped region constitute the first discharge path.

10. The ESD protection structure as claimed in claim 9, wherein the first doped region, the first well region, the third doped region, the first interconnection structure, the fourth doped region, the second well region, the third well region, and the sixth doped region constitute the second discharge path.

11. The ESD protection structure as claimed in claim 9, wherein the first doped region, the first well region, the third doped region, the first interconnection structure, the seventh doped region, the fourth well region, the fifth well region, and the eighth doped region constitute the third discharge path.

12. An ESD protection circuit for protecting a core circuit, comprising:
a substrate;
an N-type MOSFET formed on the substrate and comprising a drain which is coupled to a first input-output pad; and
a BJT formed on the substrate,
wherein:
a collector of the BJT is coupled to a gate, a source and a bulk of the N-type MOSFET,
an emitter and a base of the BJT are coupled to a second input-output pad, and
the core circuit is coupled between the first input-output pad and the second input-output pad.

13. The ESD protection circuit as claimed in claim 12, wherein:
in response to the first input-output pad receiving a first ESD voltage and the second input-output pad receiving a ground voltage, a first ESD current passes through a first diode between the drain and the bulk of the N-type MOSFET and a second diode between the collector and the base of the BJT.

14. The ESD protection circuit as claimed in claim 13, wherein the first ESD voltage is higher than the ground voltage.

15. The ESD protection circuit as claimed in claim 14, wherein:
the collector of the BJT is disposed in an N-type well region, and
there is a distance between a first projection area of the N-type well region on the substrate and a second projection area of the emitter of the BJT on the substrate.

16. The ESD protection circuit as claimed in claim 15, wherein the distance is higher than 1 μm.

17. The ESD protection circuit as claimed in claim 15, wherein in response to the first input-output pad receiving a second ESD voltage and the second input-output pad and the substrate receiving the ground voltage, a second ESD current passes through the first diode and the second diode or through the first diode and a third diode between the collector and the base of the BJT.

18. The ESD protection circuit as claimed in claim 17, wherein the second ESD voltage is lower than the ground voltage.

19. The ESD protection circuit as claimed in claim 12, wherein the gate, the source and the bulk of the N-type MOSFET, and the collector of the BJT are electrically floating.

20. The ESD protection circuit as claimed in claim 19, wherein the gate, the source, and the bulk of the N-type MOSFET are directly connected to the collector of the BJT.
